(19) United States
(12) Patent Application Publication
(10) Pub. No.: US 2019/0341233 A1
(43) Pub. Date: Nov. 7, 2019

(54) SEMICONDUCTOR SUBSTRATE PROCESSING APPARATUS AND METHOD

(71) Applicant: Applied Materials, Inc., Santa Clara, CA (US)

(72) Inventors: Andrew Nguyen, San Jose, CA (US); Yogananda Sarode Vishwanath, Bangalore (IN); Xue Chang, San Jose, CA (US)

(21) Appl. No.: 16/375,681

(22) Filed: Apr. 4, 2019

Related U.S. Application Data
(60) Provisional application No. 62/665,852, filed on May 2, 2018.

(51) Int. Cl. H01J 37/32; H01L 21/683; H01L 21/67

(52) U.S. Cl. CPC H01J 37/32816; H01L 21/6833; H01L 21/67017; H01J 2237/182; H01J 37/32568; H01J 37/32642; H01J 37/32715

(57) ABSTRACT

Embodiments described herein include a processing tool comprising configured for rapid and stable changes in the processing pressure. In an embodiment, the processing tool may comprises a chamber body. In an embodiment, the chamber body is a vacuum chamber. The processing tool may further comprise a chuck for supporting a substrate in the chamber body. In an embodiment, the processing tool may also comprise a cathode liner surrounding the chuck and a flow confinement ring aligned with the cathode liner. In an embodiment, the cathode liner and the flow confinement ring define an opening between a main processing volume and a peripheral volume of the vacuum chamber.

### CROSS-REFERENCE TO RELATED APPLICATIONS

This application claims the benefit of U.S. Provisional Application No. 62/665,852, filed on May 2, 2018, the entire contents of which are hereby incorporated by reference herein.

### BACKGROUND

### 1) Field

Embodiments relate to the field of semiconductor processing equipment and, in a particular embodiment, to a processing tool with a flow conductance regulation system for rapidly and stably changing a chamber pressure.

### 2) Description of Related Art

Processing recipes implemented by processing tools with vacuum chambers often include pressure changes. For example, the pressure may be increased or decreased in order to provide desired properties (e.g., plasma properties). Additionally, the pressure of a vacuum chamber may need to be changed in order to insert or remove a substrate from the vacuum chamber.

Changes in the pressure, such as those described above often require significant lengths of time in order for the vacuum chamber to settle at a stable pressure. Particularly, the speed at which a vacuum chamber can change pressure is limited by the flow conductance of the vacuum chamber. The flow conductance of a vacuum chamber is set, at least in part, by the configuration and components used to fabricate the vacuum chamber. For example, the diameter of the pipes, the fittings and valves, and the like may contribute to the flow conductance of a vacuum chamber.

In currently available systems, the parameters that control the flow conductance are set by the configuration of the chamber, and are not dynamically controllable. As such, changes in the pressure of a vacuum chamber cannot typically be made by changing the flow conductance of the system. Instead, the changes to the pressure of a vacuum chamber rely primarily on the performance of the pump.

### SUMMARY

Embodiments described herein include a processing tool comprising configured for rapid and stable changes in the processing pressure. In an embodiment, the processing tool may comprises a chamber body. In an embodiment, the chamber body is a vacuum chamber. The processing tool may further comprise a chuck for supporting a substrate in the chamber body. In an embodiment, the processing tool may also comprise a cathode liner surrounding the chuck and a flow confinement ring aligned with the cathode liner. In an embodiment, the cathode liner and the flow confinement ring define an opening between a main processing volume and a peripheral volume of the vacuum chamber.

Embodiments may also comprises a flow conductance regulation system. In an embodiment, the flow conductance regulation system may comprise a cathode liner and a flow confinement ring. In an embodiment, the cathode liner and the flow confinement ring are mechanically displaceable with respect to each other.

Embodiments may also comprise a processing tool configured for rapid and stable pressure changes. In an embodiment, the processing tool may comprise a chamber body. In an embodiment, the chamber body is a vacuum chamber. In an embodiment, the processing tool may also comprise a chuck for supporting a substrate in the chamber body. In an embodiment, the processing tool may also comprise a cathode liner surrounding the chuck. In an embodiment, the cathode liner and the chuck are vertically displaceable. In an embodiment, the processing tool may also comprise a flow confinement ring aligned with the cathode liner. In an embodiment, a flow conductance in the vacuum chamber is changed by displacing the cathode liner in the vertical direction.

The above summary does not include an exhaustive list of all embodiments. It is contemplated that all systems and methods are included that can be practiced from all suitable combinations of the various embodiments summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

FIG. 1A is a cross-sectional illustration of a processing tool with a fixed flow confinement ring and a displaceable cathode liner in a first position, in accordance with an embodiment.

FIG. 1B is a cross-sectional illustration of a processing tool with a fixed flow confinement ring and a displaceable cathode liner in a second position, in accordance with an embodiment.

FIG. 2A is a cross-sectional illustration of a processing tool with a grounded flow confinement ring and a displaceable cathode liner in a first position, in accordance with an embodiment.

FIG. 2B is a cross-sectional illustration of a processing tool with a grounded flow confinement ring and a displaceable cathode liner in a second position, in accordance with an embodiment.

FIG. 3A is a cross-sectional illustration of a flow confinement ring and a displaceable cathode liner in a first position, in accordance with an embodiment.

FIG. 3B is a cross-sectional illustration of a flow confinement ring and a displaceable cathode liner in a second position, in accordance with an embodiment.

FIG. 4A is a cross-sectional illustration of a grounded flow confinement ring and a displaceable cathode liner with a notch in a first position, in accordance with an embodiment.

FIG. 4B is a cross-sectional illustration of a flow confinement ring and a displaceable cathode liner with a notch in a second position, in accordance with an embodiment.

FIG. 5A is a cross-sectional illustration of a flow confinement ring and a displaceable cathode liner with a baffle in a first position, in accordance with an embodiment.

FIG. 5B is a cross-sectional illustration of a flow confinement ring and a displaceable cathode liner with a baffle in a second position, in accordance with an embodiment.

FIG. 6A is a cross-sectional illustration of a grounded flow confinement ring with an RF gasket and a displaceable cathode liner in a first position, in accordance with an embodiment.

FIG. 6B is a cross-sectional illustration of a grounded flow confinement ring with an RF gasket and a displaceable cathode liner in a second position in accordance with an embodiment.

FIG. 7A is a cross-sectional illustration of a flow confinement ring with a protrusion and a displaceable cathode liner with a recess in a first position, in accordance with an embodiment.

FIG. 7B is a cross-sectional illustration of a flow confinement ring with a protrusion and a displaceable cathode liner with a recess in a second position, in accordance with an embodiment.

FIG. 8A is a cross-sectional illustration of a flow confinement ring with a surface that is complementary to a surface on a displaceable cathode liner that is in a first position, in accordance with an embodiment.

FIG. 8B is a cross-sectional illustration of a flow confinement ring with a surface that is complementary to a surface on a displaceable cathode liner that is in a second position, in accordance with an embodiment.

FIG. 9A is a cross-sectional illustration of a flow confinement ring with a plurality of flow regulating openings of varying size, in accordance with an embodiment.

FIG. 9B is a cross-sectional illustration of a flow confinement ring with a plurality of vertical slots with varying widths, in accordance with an embodiment.

FIG. 9C is a cross-sectional illustration of a flow confinement ring with a plurality of circular slots with varying diameters, in accordance with an embodiment.

FIG. 9D is a cross-sectional illustration of a flow confinement ring with a plurality of horizontal slots with varying thicknesses, in accordance with an embodiment.

FIG. 9E is a perspective view illustration of a flow confinement ring with non-uniform openings radially arranged around the perimeter of the flow confinement ring, in accordance with an embodiment.

FIG. 9F is a cross-section of the flow confinement ring in FIG. 9E, in accordance with an embodiment.

FIG. 10 is a cross-sectional illustration of a processing tool with a displaceable confinement ring and a displaceable cathode liner, in accordance with an embodiment.

FIG. 11 illustrates a block diagram of an exemplary computer system that may be used in conjunction with a flow conductance regulation system, in accordance with an embodiment.

### DETAILED DESCRIPTION

Devices in accordance with embodiments described herein include a vacuum processing chamber with a configurable flow conductance. In a particular embodiment, a cathode liner and a flow confinement ring are displaceable with respect to each other in order to provide a rapid change in the flow conductance. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, current systems do not include a mechanism to rapidly and stably change the pressure in a vacuum chamber. Accordingly, embodiments described herein include a system for rapidly and stably changing the pressure in a vacuum chamber by controlling a flow conductance in the chamber. Particularly, embodiments include a cathode liner and a flow confinement ring that are displaceable with respect to each other. The cathode liner and the flow confinement ring separate a main processing volume of the chamber from a peripheral volume of the chamber. An opening defined by the surfaces of the cathode liner and the flow confinement ring fluidically couples the main processing volume of the chamber to the peripheral volume of the chamber. As such, displacing the cathode liner and the flow confinement ring with respect to each other changes the geometry of the opening and, therefore, changes the flow conductance between the main processing volume and the peripheral volume of the chamber.

Since the change in flow conductance is the result of mechanical displacement of the cathode liner and/or the flow confinement ring, rapid changes in the pressure of the main processing volume are possible. For example, embodiments described herein enable a change in the pressure of the main processing volume that is 50 mT or greater in approximately five seconds or less. Additional embodiments may enable a change in the pressure of the main processing volume that is 70 mT or greater in less than three seconds.

Embodiments of the invention also provide mechanisms for improved precision during rapid pressure changes. For example, embodiments include cathode liners and flow confinement rings that include profiles that further refine the flow conductance of the opening. In some embodiments, the cathode liner and/or the flow confinement ring include a plurality of slots with decreasing dimensions. As more of the slots are covered and the flow conductance is reduced, the resolution of changes to the flow conductance is increased.

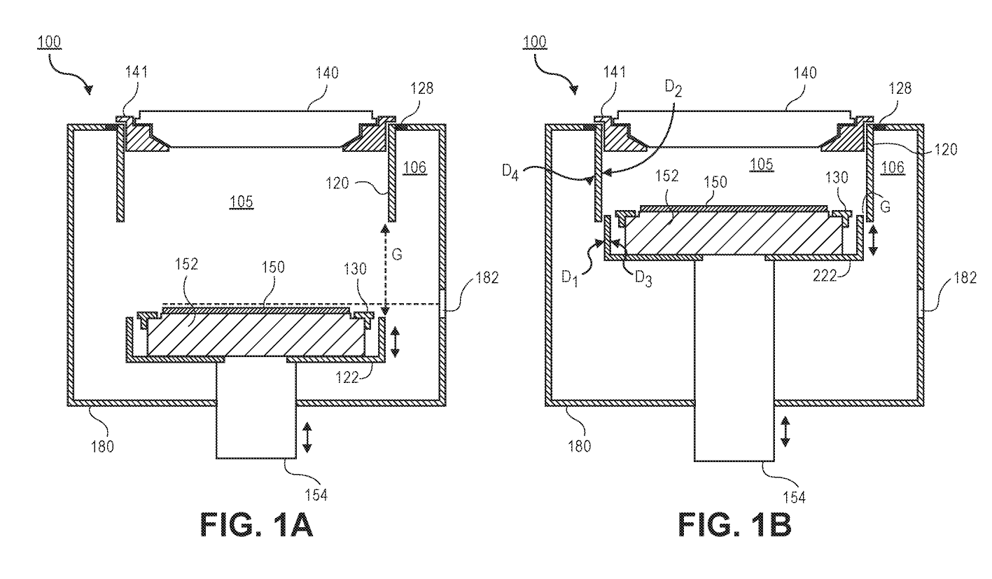

Referring now to FIG. 1A, a cross-sectional illustration of a processing tool 100 with a flow conductance regulation system is shown, in accordance with an embodiment. In an embodiment, the processing tool 100 may include a chamber body 180. The chamber body 180 may be any suitable vacuum chamber of any size to accommodate the processing of one or more substrates 150. In an embodiment, the chamber body 180 may include a lid 141. In an embodiment, the lid 141 may support a gas distribution plate 140, such as a showerhead. The chamber body 180 may include a port 182 for inserting a substrate into the chamber body 180. For example, the illustrated embodiment includes a port 182 that is a side loading door, though embodiments are not limited to side-loading ports. While not illustrated, it is to be appreciated that one or more exhaust ports may also be formed through the chamber body 180.

In an embodiment, substrates 150 in the chamber body 180 may be supported by a chuck 152. The chuck 152 may be an electrostatic chuck in some embodiments. In an embodiment, the chuck 152 may include heating and/or cooling systems to provide a desired substrate temperature during processing. A process kit 130 may be coupled to the chuck 152 around an outer edge of the substrate 150. In an embodiment, the chuck 152 may be coupled to a pedestal 154. In an embodiment, the pedestal 154 may be displaceable. For example, the arrows proximate to the pedestal 154 indicate that the pedestal 154 is displaceable in at least the vertical direction (i.e., Z-direction).

In an embodiment, the processing tool 100 may include a flow conductance regulation system that comprises a cathode liner 122 and a flow confinement ring 120. In an embodiment, the flow confinement ring 120 may be coupled to the lid 141 of the chamber body 180. In an embodiment, the flow confinement ring has a floating voltage (i.e., the flow confinement ring is not grounded). For example, in FIGS. 1A and 1B the flow confinement ring 120 is electrically isolated from the grounded chamber body 180 by an insulator 128. However, it is to be appreciated that in some embodiments the flow confinement ring 120 may be grounded and the component 128 may be a conductor. In an embodiment, the cathode liner 122 may surround the outer perimeter of the chuck 152. The cathode liner 122 may also be coupled to the pedestal 154. Accordingly, the cathode liner 122 may be displaceable in at least one direction (as indicated by the arrows) in some embodiments.

In an embodiment, the flow conductance regulation system provides a system for regulating the flow conductance between a main processing volume 105 and a peripheral chamber volume 106. In an embodiment, the flow conductance is regulated by displacing the cathode liner 122 with respect to the flow confinement ring 120. For example, the cathode liner 122 may be displaced towards or away from the flow confinement ring 120 by displacing the pedestal 154.

In an embodiment, the displacement of the cathode liner 122 with respect to the flow confinement ring 120 results in a change to the geometry of a gap G defined by surfaces of the flow confinement ring 120 and the cathode liner 122. The gap G fluidically couples the main processing volume 105 to the peripheral volume 106.

In FIG. 1A the cathode liner 122 is in a first position. The first position may provide a gap G that provides a large flow conductance. For example, the flow conductance may be sufficient to provide low pressure processing in the main processing volume 105. For example, the main processing volume 105 may be operable at approximately 20 mT or less when the cathode liner 122 is in the first position. In an embodiment, when the cathode liner 122 is in the first position substrates 150 may be insertable through the opening 182 to be placed on or removed from the chuck 152, as indicated by the dashed line.

In FIG. 1B the cathode liner 122 is in a second position. The second position may provide a gap G that provides a low flow conductance. For example, the flow conductance may be sufficient to provide relatively high pressure processing in the main processing volume 105. For example, the main processing volume 105 may be operable at approximately 50 mT or more when the cathode liner 122 is in the second position.

While the cathode liner 122 is shown in a first position in FIG. 1A and a second position in FIG. 1B, it is to be appreciated that the cathode liner 122 may be moved to any position between the first position and the second position in order to provide a desired flow conductance. As such, embodiments allow for the main processing volume 105 to be maintained at any desired pressure by moving the cathode liner 122 to any desired position. In accordance with an embodiment, the flow conductance regulation system may enable a pressure change in the main processing volume 105 that is 50 mT or greater in approximately five seconds or less. Additional embodiments may enable a change in the pressure of the main processing volume 105 that is 70 mT or greater in less than three seconds. It is to be appreciated that since the flow conductance is modified by mechanical displacement of components in the processing tool, the changes in pressure of the main processing volume are stabilized quicker than is possible when relying only on a pump.

In an embodiment, the cathode liner 122 and the flow confinement ring 120 may be substantially concentric with each other. In an embodiment, a diameter D₁ of an outer surface of the cathode liner 122 may be smaller than a diameter D₂ of an inner surface of the flow confinement ring 120. As such, the cathode liner 122 may be displaced towards the flow confinement ring 120 so that portions of the cathode liner 122 are surrounded by the flow confinement ring 120, as shown in FIG. 1B. However, it is to be appreciated that in some embodiments a diameter D₃ of an inner surface of the cathode liner 122 may be greater than a diameter D₄ of an outer surface of the flow confinement ring 120. In such embodiments, portions of the flow confinement ring 120 may be encircled by the cathode liner 122. In some embodiments, the outer diameters D₁ and D₄ of the cathode liner 122 and the flow confinement ring 120 may be substantially the same. Furthermore, while the cathode liner 122 and the flow confinement ring 120 are described as circular rings, it is to be appreciated that one or both of the cathode ring 122 and the flow confinement ring 120 may have non-circular shapes (e.g., square, rectangular, elliptical, or the like).

In some embodiments, alignment pads may be formed on the surfaces of the flow confinement ring 120 and the cathode liner 122 that face each other in order to maintain a substantially concentric alignment. The alignment pads may also be insulating alignment pads in order to ensure the cathode liner 122 is electrically isolated from the flow confinement ring 120. For example, the alignment pads may be Teflon or the like.

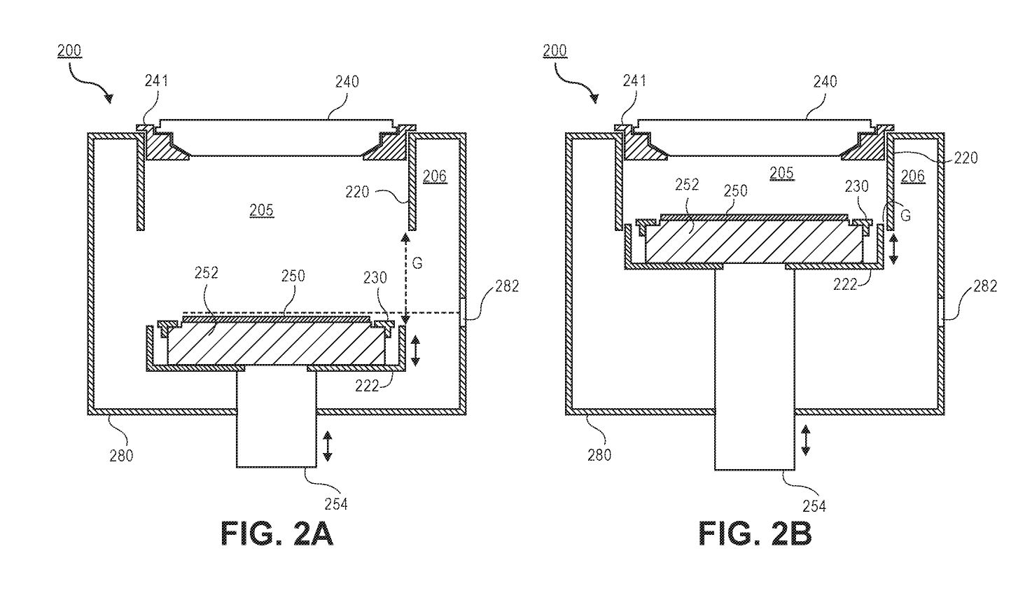

Referring now to FIGS. 2A and 2B, a processing 200 with a cathode liner 222 in a first position (FIG. 2A) and a second position (FIG. 2B) is shown, in accordance with an additional embodiment. The processing tool 200 may be substantially similar to the processing tool 100 illustrated in FIGS. 1A and 1B with the exception that the flow confinement ring 220 is grounded. In an embodiment, the flow confinement ring 220 is grounded by being electrically coupled to the chamber body 280. In some embodiments, the flow confinement ring 220 may be integrated with the chamber body 280.

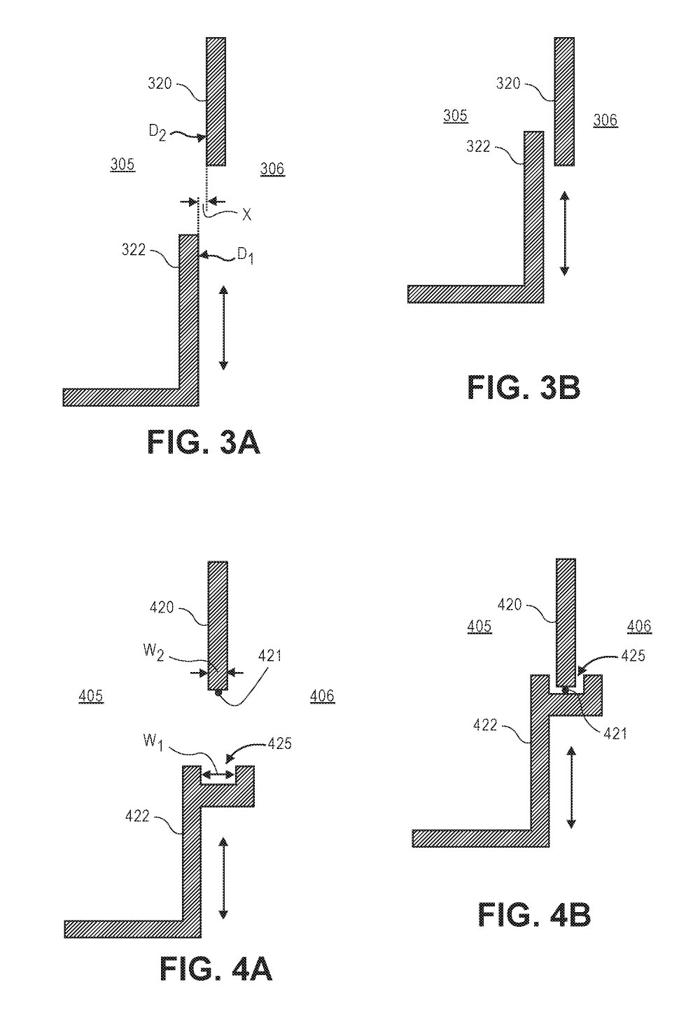

Referring now to FIGS. 3A and 3B, portions of a cathode liner 322 and a flow confinement ring 320 are shown, in accordance with an embodiment. In an embodiment, an outer surface of the cathode liner 322 has a diameter D₁ that is less than a diameter D₂ of the inner surface of the flow confinement ring 320. For example, the diameter D₂ of the inner surface of the flow confinement ring 320 may be greater than the diameter D₁ of the outer surface of the cathode liner 322 by a distance X. In an embodiment, the distance X may be approximately 0.25 inches, however it is to be appreciated that the distance X may be any suitable dimension depending on the design of the processing tool.

In FIG. 3B the cathode liner 322 is displaced towards the flow confinement ring 322. As the cathode liner 322 is displaced towards the flow confinement ring 320, the gap between the main processing volume 305 and the peripheral volume 306 is decreased. In some embodiments, the cathode liner 322 may overlap with the flow confinement ring 320. As the cathode liner 322 is displaced towards the flow confinement ring 320, the flow conductance between the main processing volume 305 and the peripheral volume 306 is reduced.

Referring now to FIGS. 4A and 4B, portions of a cathode liner 422 and a grounded flow confinement ring 420 are shown, in accordance with an embodiment. In such embodiments, the flow confinement ring 420 may be grounded by being an integral part of a grounded chamber body (similar to FIGS. 2A and 2B) or the flow confinement ring 420 may be electrically coupled to a grounded component (similar to FIGS. 1A and 1B, where component 128 is a conductor). In an embodiment, the cathode liner 422 may include a notch 425. In an embodiment, the notch 425 may be sized to receive an end of the flow confinement ring 420. For example, the notch 425 may have a width W₁ that is equal to or larger than a width W₂ of the flow confinement ring 420. In an embodiment, an RF gasket 421 may be formed on the end of the flow confinement ring 420. The RF gasket 421 may electrically isolate the flow confinement ring 420 from the cathode liner 422 when the flow confinement ring 420 is set in the notch 425 of the cathode liner 422, as shown in FIG. 4B. As the cathode liner 422 is displaced towards the flow confinement ring 420, the flow conductance between the main processing volume 405 and the peripheral volume 406 is reduced. Furthermore, it is to be appreciated that the RF gasket 421 does not need to provide a complete seal in all embodiments. For example, a gap may be present between the flow confinement ring 420 and the cathode liner 422 in order to allow fluid flow between the components.

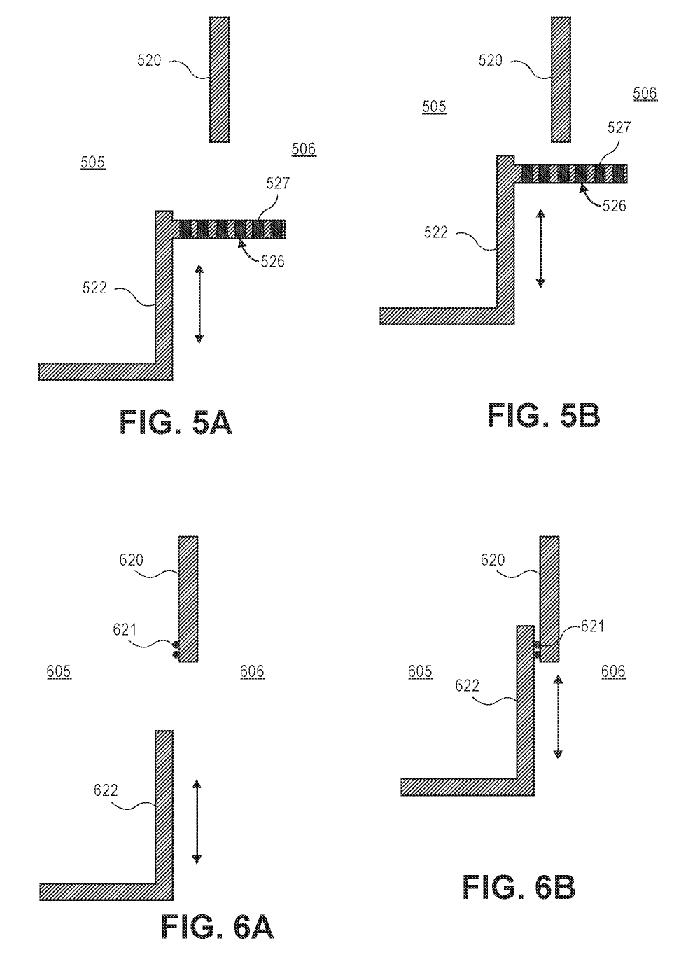

Referring now to FIGS. 5A and 5B, portions of a cathode liner 522 and a flow confinement ring 520 are shown, in accordance with an embodiment. In an embodiment, the cathode liner 522 may include a baffle 526. In the illustrated embodiment, the baffle 526 is illustrated as having multiple through-holes 527. However, it is to be appreciated that embodiments may include a baffle 526 with any number of channels and/or through-holes. The flow confinement ring 520 may be positioned over the baffle 526. In an embodiment, the baffle modifies the flow conductance between the main processing volume 505 and the peripheral volume 506 when the cathode liner 522 is brought close to the flow confinement ring 520, as shown in FIG. 5B.

Referring now to FIGS. 6A and 6B, portions of a cathode liner 622 and a flow confinement ring 620 are shown, in accordance with an embodiment. In an embodiment, an RF gasket 621 may be formed on the interior surface of the flow confinement ring 620. In an embodiment, the RF gasket 621 may electrically isolate the flow confinement ring 620 from the cathode liner 622 when the cathode liner 622 is displaced so that it is proximate to the flow confinement ring 620, as shown in FIG. 6B. Furthermore, it is to be appreciated that the RF gasket 621 does not need to provide a complete seal in all embodiments. For example, a gap may be present between the flow confinement ring 620 and the cathode liner 622 in order to allow fluid flow between the components.

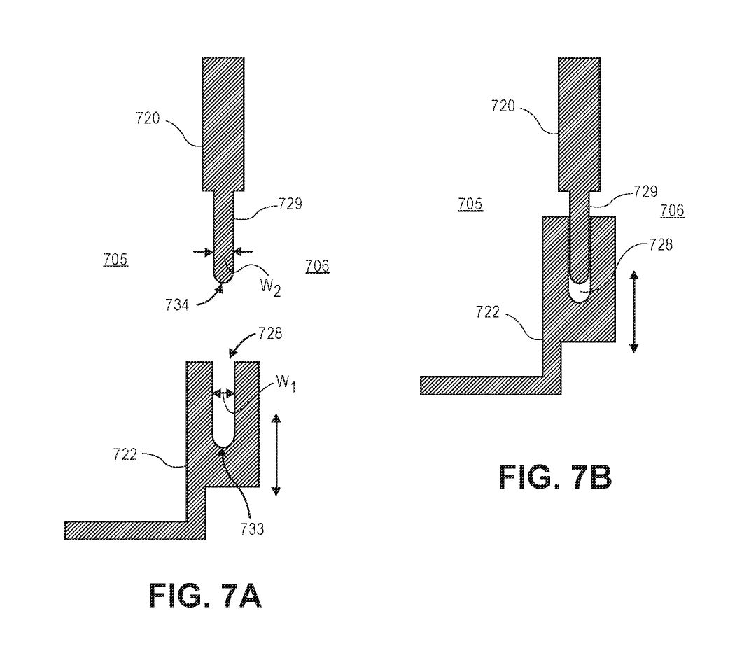

Referring now to FIGS. 7A and 7B, portions of a cathode liner 722 and a flow confinement ring 720 are shown, in accordance with an embodiment. In an embodiment, the flow confinement ring 720 may include a protrusion 729 that is sized to fit into a recess 728 formed into the cathode liner 722. For example, a width W₁ of the recess 728 may be equal to or larger than a width W₂ of the protrusion 729. In an embodiment, the surface 733 of the recess 728 may substantially match the surface 734 of the protrusion. For example, the protrusion surface 734 may be rounded, and the surface 733 of the recess may be rounded to match the protrusion surface 734. In an embodiment, the interface between the protrusion 729 and the recess 728 may be referred to as a male-female interface.

In an embodiment, as the cathode liner 722 is displaced towards the flow confinement ring 722, the protrusion 729 fills the recess 728. As more of the protrusion 729 enters the recess 728 the flow conductance between the main processing volume 705 and the peripheral volume 706 is reduced.

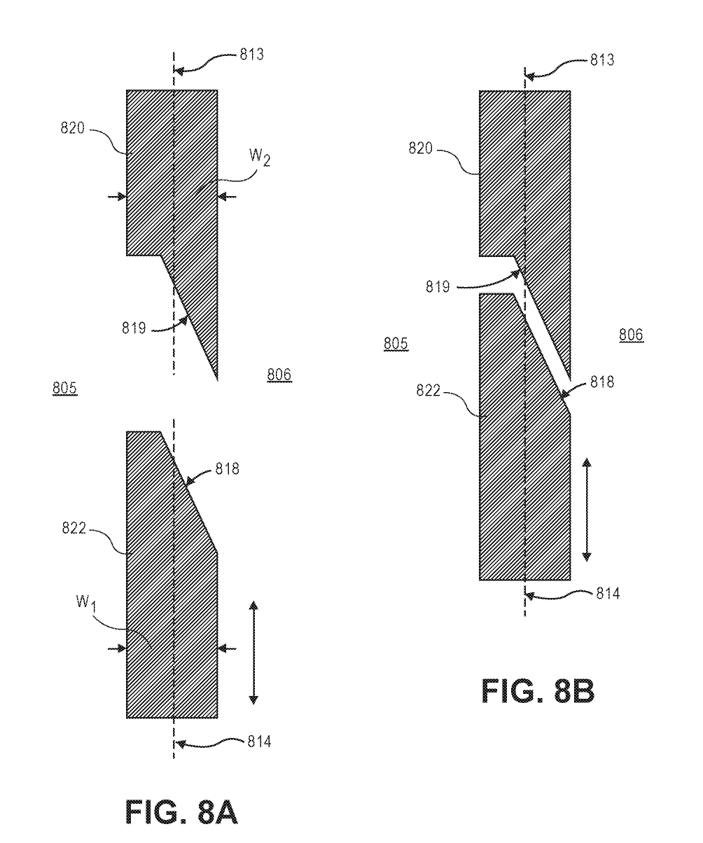

Referring now to FIGS. 8A and 8B, portions of a cathode liner 822 and a flow confinement ring 820 are shown, in accordance with an embodiment. In an embodiment, the cathode liner 822 has a surface 818 that is complimentary to a surface 819 of the flow confinement ring 820. In an embodiment, centerlines 813 and 814 of the flow confinement ring 820 and the cathode liner 822 may be substantially aligned. In an embodiment, a width W₁ of the cathode liner 822 may be substantially equal to a width of the flow confinement ring 820. In additional embodiments, the width W₁ of the cathode liner 822 may be different than a width W₂ of the cathode liner 822. As the cathode liner 822 is displaced towards the flow confinement ring 822 the flow conductance between the main processing volume 805 and the peripheral volume 806 is reduced.

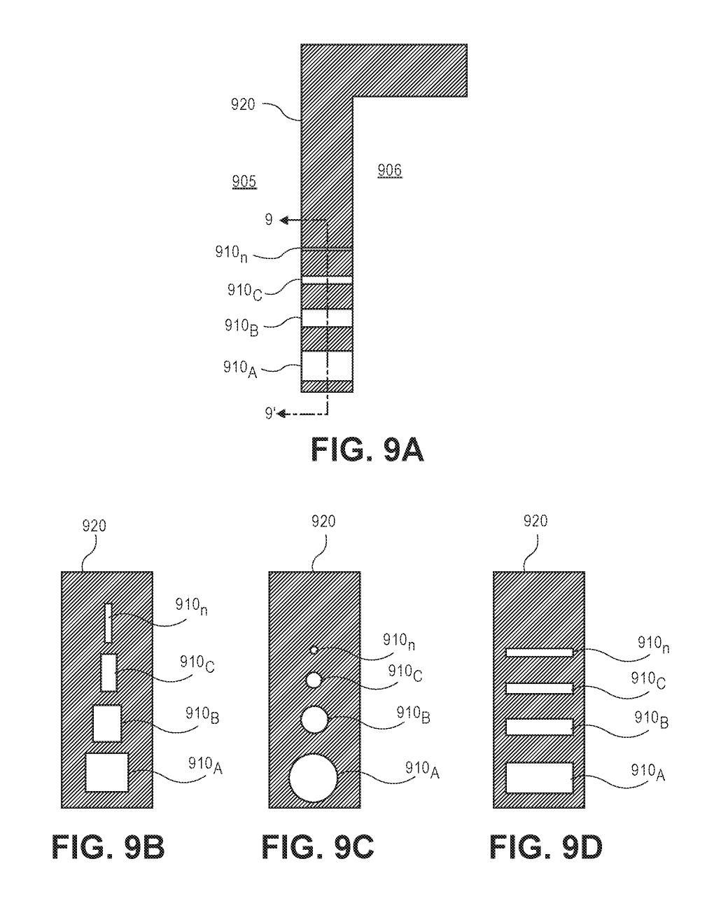

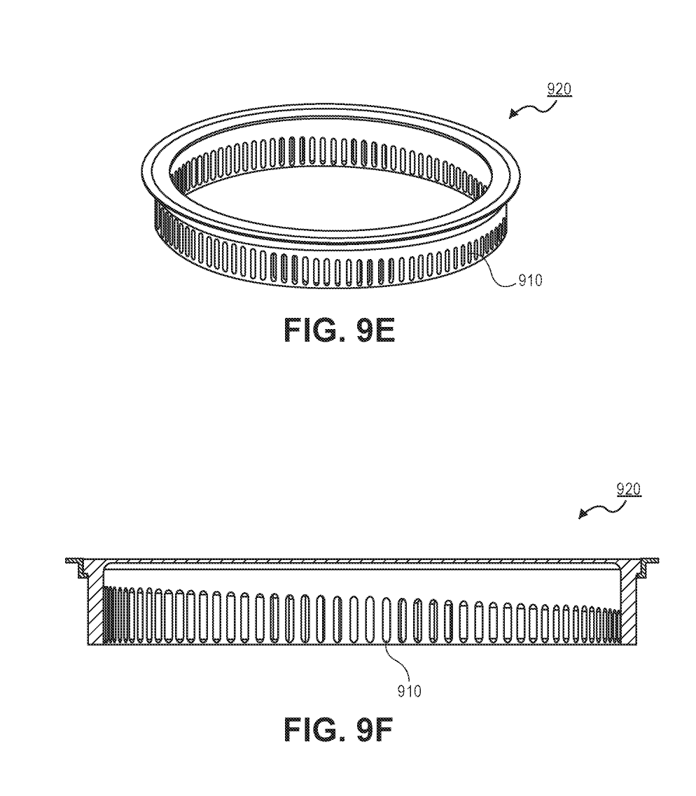

Referring now to FIG. 9A, a cross-sectional illustration of a portion of a flow confinement ring 920 is shown, in accordance with an embodiment. In an embodiment, the flow confinement ring 920 may include a plurality of slots 910_{A}-910ₙ. The presence of the slots 910 allows for further control of the flow conductance between the main processing volume 905 and the peripheral volume 906. For example, as the cathode liner is displaced towards the flow confinement ring 920, the slots 910 become blocked. In some embodiments, the slots 910 have a non-uniform dimension. For example, the slots may have progressively smaller dimensions. Such embodiments allow for the more precise control of the flow conductance as the flow conductance is decreased.

Embodiments include slots with any shape. Exemplary embodiments of slots 910 are shown in FIGS. 9B-9D. For example, in FIG. 9B the slots 910_{A}-910ₙ are shown as vertical slots with different widths. In FIG. 9C the slots 910_{A}-910ₙ are shown as circular slots with different diameters. In FIG. 9D the slots 910_{A}-910ₙ are shown as lateral slots with different thicknesses. While the slots 910 are illustrated as being formed on the flow confinement ring 910, it is to be appreciated that slots may also be formed on the cathode liner. In some embodiments, slots may be formed on the cathode liner and the flow confinement ring.

Referring now to FIG. 9E, a perspective view illustration of a flow confinement ring 920 with a plurality of slots 910 arranged around a perimeter of the flow confinement ring 920 is shown, in accordance with an embodiment. As shown, the slots 910 may be substantially of uniform width and have a substantially uniform spacing around the perimeter. In some embodiments, the slots 910 may include non-uniform heights. The variation in the height of the slots 910 is more clearly visible in FIG. 9F. As shown, the bottom surfaces of each of the slots 910 may be substantially aligned with each other (in the Z-direction). Due to the variation in the height of the slots 910, the top surfaces of the slots 910 are not aligned with each other (in the Z-direction). In the illustrated embodiment, the slots 910 are ordered by height. However, it is to be appreciated that the slots 910 may be arranged in any suitable order.

The use of slots 910 with non-uniform heights allows for improved control of the flow conductance. For example, once the shortest slot 910 is covered by the cathode liner (not shown), the number of slots 910 that remain partially exposed continues to decrease as the cathode liner continues to advance. This provides more precise control at lower flow conductance values.

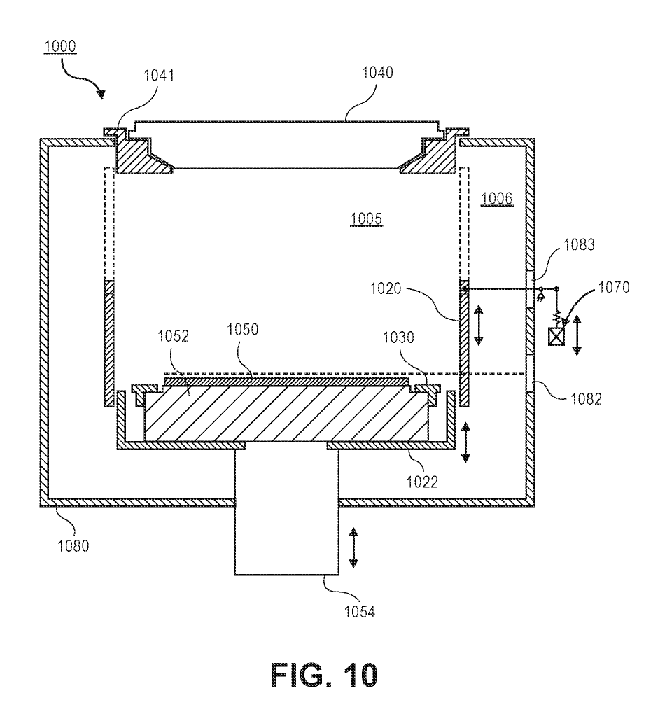

Referring now to FIG. 10, a cross-sectional illustration of a tool 1000 with a displaceable flow confinement ring 1020 and a displaceable cathode liner 1022 is shown, in accordance with an embodiment. In an embodiment, the flow confinement ring 1020 may be displaced in at least one direction as indicated by the dashed lines and the arrow by an actuator 1070 that is located outside of the chamber body 1080. In an embodiment, the actuator 1070 may be mechanically coupled to the flow confinement ring 1020 through a window 1083. In some embodiments, the cathode liner 1022 may be stationary and the flow confinement ring 1020 may be the only displaceable component.

Embodiments described herein include processing tools with a single main processing volume. However, it is to be appreciated that embodiments may also include flow conductance regulation systems that are integrated into processing tools with two or more main processing volumes. For example, a processing tool may include two or more flow conductance regulation systems in order to process a plurality of substrates simultaneously.

Embodiments described herein also may include processing tools that have been retrofitted to include a flow conductance regulation system. In processing tools that include a displaceable chuck, the tool may be modified by installing a flow confinement ring similar to those described above. In processing tools without a displaceable chuck, a displaceable flow confinement ring similar to the one described in FIG. 10 may be installed.

Furthermore, it is to be appreciated that the profiles of the cathode liner and the flow confinement ring may be any profile described with respect to embodiments described herein. For example, the processing tools 100, 200, and 1000 may include cathode liners and/or flow confinement rings that include one or more of the profiles described with respect to FIGS. 3A-9C.

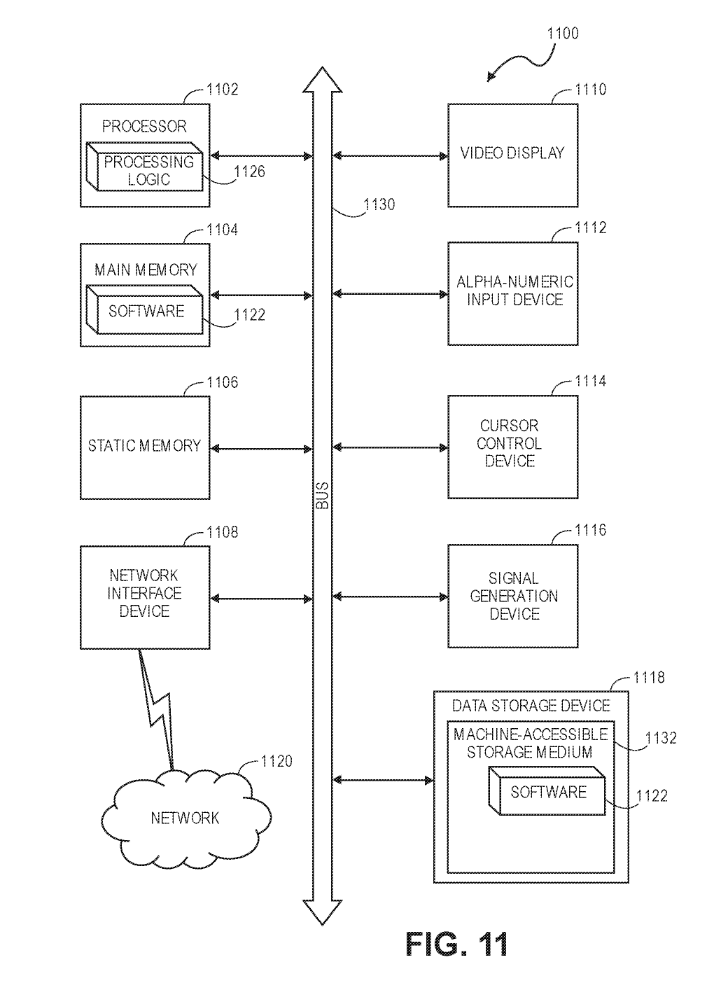

Referring now to FIG. 11, a block diagram of an exemplary computer system 1160 of a processing tool is illustrated in accordance with an embodiment. In an embodiment, computer system 1160 is coupled to and controls processing in the processing tool. Computer system 1160 may be connected (e.g., networked) to other machines in a Local Area Network (LAN), an intranet, an extranet, or the Internet. Computer system 1160 may operate in the capacity of a server or a client machine in a client-server network environment, or as a peer machine in a peer-to-peer (or distributed) network environment. Computer system 1160 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1160, the term “machine” shall also be taken to include any collection of machines (e.g., computers) that individually or jointly execute a set (or multiple sets) of instructions to perform any one or more of the methodologies described herein.

Computer system 1160 may include a computer program product, or software 1122, having a non-transitory machine-readable medium having stored thereon instructions, which may be used to program computer system 1160 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1160 includes a system processor 1102, a main memory 1104 (e.g., read-only memory (ROM), flash memory, dynamic random access memory (DRAM) such as synchronous DRAM (SDRAM) or Rambus DRAM (RDRAM), etc.), a static memory 1106 (e.g., flash memory, static random access memory (SRAM), etc.), and a secondary memory 1118 (e.g., a data storage device), which communicate with each other via a bus 1130.

System processor 1102 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1102 may also be one or more special-purpose processing devices such as an application specific integrated circuit (ASIC), a field programmable gate array (FPGA), a digital signal system processor (DSP), network system processor, or the like. System processor 1102 is configured to execute the processing logic 1126 for performing the operations described herein.

The computer system 1160 may further include a system network interface device 1108 for communicating with other devices or machines. The computer system 1160 may also include a video display unit 1110 (e.g., a liquid crystal display (LCD), a light emitting diode display (LED), or a cathode ray tube (CRT)), an alphanumeric input device 1112 (e.g., a keyboard), a cursor control device 1114 (e.g., a mouse), and a signal generation device 1116 (e.g., a speaker).

The secondary memory 1118 may include a machine-accessible storage medium 1131 (or more specifically a computer-readable storage medium) on which is stored one or more sets of instructions (e.g., software 1122) embodying any one or more of the methodologies or functions described herein. The software 1122 may also reside, completely or at least partially, within the main memory 1104 and/or within the system processor 1102 during execution thereof by the computer system 1160, the main memory 1104 and the system processor 1102 also constituting machine-readable storage media. The software 1122 may further be transmitted or received over a network 1120 via the system network interface device 1108.

While the machine-accessible storage medium 1131 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A processing tool comprising:
a chamber body, wherein the chamber body is a vacuum chamber;
a chuck for supporting a substrate in the chamber body;
a cathode liner surrounding the chuck; and
a flow confinement ring aligned with the cathode liner, wherein the cathode liner and the flow confinement ring define an opening between a main processing volume and a peripheral volume of the vacuum chamber.

2. The processing tool of claim 1, wherein the cathode liner is displaceable, and wherein displacing the cathode liner changes a geometry of the opening.

3. The processing tool of claim 2, wherein the cathode liner is coupled to the chuck, and wherein the cathode liner and the chuck are displaced at the same time.

4. The processing tool of claim 2, wherein the flow confinement ring is coupled to a chamber lid.

5. The processing tool of claim 4, wherein the flow confinement ring is grounded.

6. The processing tool of claim 4, wherein the flow confinement ring is not grounded.

7. The processing tool of claim 1, wherein the flow confinement ring is displaceable, and wherein displacing the flow confinement ring changes a geometry of the opening.

8. The processing tool of claim 7, wherein the confinement ring is displaced by an actuator that is outside of the vacuum chamber.

9. The processing tool of claim 1, wherein the flow confinement ring and the cathode liner are displaceable, and wherein displacing the flow confinement ring or the cathode liner changes a geometry of the opening.

10. A flow conductance regulation system, comprising:
a cathode liner; and
a flow confinement ring, wherein the cathode liner and the flow confinement ring are mechanically displaceable with respect to each other.

11. The flow conductance regulation system of claim 10, wherein the flow confinement ring is coupled to a lid of a chamber, and wherein the cathode liner is coupled to a chuck in the chamber.

12. The flow conductance regulation system of claim 10, wherein an inner diameter of the flow confinement ring is greater than an outer diameter of the cathode liner.

13. The flow conductance regulation system of claim 10, wherein the cathode liner comprises a notch that is sized to receive the flow confinement ring.

14. The flow conductance regulation system of claim 10, wherein the cathode liner comprises a baffle.

15. The flow conductance regulation system of claim 10, wherein the flow confinement ring comprises a protruding member, and wherein the cathode liner comprises a recess sized to receive the protruding member of the flow confinement ring.

16. The flow conductance regulation system of claim 10, wherein the flow confinement ring and the cathode liner have complementary surfaces.

17. The flow conductance regulation system of claim 10, wherein the flow confinement ring includes a plurality of slots with different dimensions.

18. A processing tool comprising:
a chamber body, wherein the chamber body is a vacuum chamber;
a chuck for supporting a substrate in the chamber body;
a cathode liner surrounding the chuck, wherein the cathode liner and the chuck are vertically displaceable; and
a flow confinement ring aligned with the cathode liner, wherein a flow conductance in the vacuum chamber is changed by displacing the cathode liner in the vertical direction.

19. The processing tool of claim 18, wherein displacing the cathode liner from a first position to a second position results in a pressure change of at least 50 mT in the vacuum chamber.

20. The processing tool of claim 19, wherein the pressure change is stabilized in approximately three seconds or less.
